(19) United States
(12) Patent Application Publication
(10) Pub. No.: US 2026/0076207 A1
(43) Pub. Date: Mar. 12, 2026

(54) SELECTIVE BACKSIDE ETCH FOR 3-D IC STACK

(71) Applicant: pSemi Corporation, San Diego, CA (US)

(72) Inventors: Saloni CHAURASIA, SAN DIEGO, CA (US); Shishir RAY, SAN DIEGO, CA (US); Panglijen CANDRA, SAN DIEGO, CA (US)

(21) Appl. No.: 18/830,463

(22) Filed: Sep. 10, 2024

(51) Int. Cl. H01L 23/552; H01L 21/3065; H01L 21/683; H01L 21/762; H01L 23/522; H01L 25/065

(52) U.S. Cl. CPC H10W 42/20; H10P 50/242; H10P 72/74; H10P 90/1914; H10W 10/181; H10W 20/42; H10W 90/00; H10W 90/297

(57) ABSTRACT

Integrated circuit structures and fabrication methods that substantially prevent or mitigate damage that plasma etching may cause to the FETs of a top integrated circuit in a 3-D integrated circuit (IC) stack. Embodiments of such IC structures include (1) use of substrate contacts (S-contacts) within the top integrated circuit, IC_{T}, of the 3-D IC stack connected to the gates of FETs that may be damaged by plasma etching, and (2) selective retention of the substrate/handle wafer of IC_{T} aligned and in electrical contact with such S-contacts so as to conduct plasma charge away from the gate oxide of the protected FETs. In addition, the novel integrated circuit structures provide an additional benefit by providing thermal dissipation paths (heat sinks) for the 3-D IC stack.

### TECHNICAL FIELD

The present invention relates to three-dimensional integrated circuit structures and circuits and methods for making such structures and circuits.

### BACKGROUND

The electronics industry continues to strive for ever-increasing electronic functionality and performance in a wide variety of products, including (by way of example only) personal electronics (e.g., “smart” watches and fitness wearables), personal computers, tablet computers, wireless network components, televisions, cable system “set top” boxes, radar systems, and cellular telephones. Increased functionality and/or performance commonly translates to more transistors and other electronic components on an integrated circuit (IC) die. While the number of transistors per unit area of an IC die has increased over time as IC manufacturing process nodes have shrunk device dimensions, the two-dimensional (2-D) planar “footprint” of some IC dies has not decreased at the same rate, primarily owing to the use of more (albeit smaller) transistors to implement increased functionality and/or performance. The 2-D footprint of an IC die is one constraint on reducing the size of modules and circuit boards within electronic products.

In order to shrink the 2-D footprint of an IC die, a number of three-dimensional (3-D) technologies have been developed that have focused on stacking and bonding aligned IC dies on different wafers (also known as wafer-to-wafer bonding), stacking and bonding individual IC dies on non-singulated IC dies on a wafer (also known as die-to-wafer bonding), and stacking and bonding an individual IC die on another IC die (also known as die-to-die bonding). One such technology may be referred to as “hybrid bonding interconnect” (HBI), in which two 2-D ICs are fabricated on different wafers or dies and then vertically stacked in a 3-D structure, with, for example, about half of the circuitry formed on a first or “bottom” wafer/die, and about half of the circuitry formed on a second or “top” wafer or die that is then bonded to the bottom wafer/die. Bonding of the two wafers/dies using HBI generally uses both dielectric materials (e.g., silicon dioxide, SiCN, SiCOH, and/or analogous alloys) and conductive interconnect materials (e.g., copper, aluminum, and/or their alloys).

HBI technology allows for a number of different stacking structures. By way of background, FIG. 1A is a cross-sectional view of one stage of fabrication of a prior art 3-D IC 100 involving a stack of two 2-D ICs. This example involves the bonding of a bonding face 101 of a first IC (IC_{T} for “top” IC) to a bonding face 101 of a second IC (IC_{B} for “bottom” IC). In this particular example, both ICs are fabricated using a silicon-on-insulator (SOI) fabrication process, and may or may not be identical.

In the illustrated example, each of IC_{T} and IC_{B} are formed in essentially the same manner. Starting with a substrate/handle wafer 102 (e.g., a silicon wafer, including a high-resistivity Si wafer), an insulating buried oxide (BOX) layer 104 is formed, on which an active layer 106 is formed. The active layer 106 may be, for example, silicon, germanium, or an SiGe alloy. In the illustrated example, a field-effect transistor comprising a source S, gate G, body B, and drain D has been formed in and on the active layer 106. Various other known structures, such as isolation regions, may also be formed in known fashion. The IC fabrication process up to this point is generally considered the front-end-of-line (FEOL) where individual devices (transistors, capacitors, resistors, inductors etc.) are patterned in or on the active layer 106. The FEOL generally covers everything up to (but not including) the deposition of metal interconnect layers.

After the last FEOL step, a wafer generally consists of isolated transistors without any interconnecting conductors. The back end of line (BEOL) is the second portion of IC fabrication where the individual devices (transistors, capacitors, resistors, inductors, etc.) are interconnected with conductors formed as part of or between one or more metal interconnect layers within a superstructure 108. The superstructure 108 is generally built up with multiple layers and may include one or more metal levels 110 (e.g., M1, M2, M3), internal vias 112, and IC bonding vias 114 within a matrix of inter-layer dielectric (ILD) material (to avoid clutter, not all instances of such structures are labelled). In some applications, the superstructure 108 of IC_{T} and/or IC_{B} may also include electronic components such as capacitors, resistors, and inductors. An exposed surface of the superstructure 108 of IC_{T} and IC_{B} comprises the bonding face 101 of each IC.

In FIG. 1A, the bonding face 101 of IC_{T} is shown being aligned with the bonding face 101 of IC_{B} and being moved towards IC_{B} for bonding, as indicated by the arrows 116. FIG. 1B is a cross-sectional view of a further stage of fabrication of the prior art 3-D IC 100 of FIG. 1A. In FIG. 1B, IC_{T} has been bonded to IC_{B}, and the substrate/handle wafer 102 has been removed from IC_{T}, such as by chemical-mechanical polishing (CMP). Removing the substrate/handle wafer 102 from IC_{T} allows access to the backside of IC_{T} for formation of additional structures.

FIG. 1C is a cross-sectional view of yet a further stage of fabrication of the prior art 3-D IC 100 of FIG. 1A. A backside structure 118 has been formed, generally comprising multiple layers that may include one or more backside metal levels 120 (e.g., BS-M1, BS-M2), internal vias 122, and backside bonding vias 124 (e.g., BS-Pad) within a matrix of inter-layer dielectric (ILD) material (to avoid clutter, not all instances of such structures are labelled). In addition, electrically conductive through-BOX vias (TBVs) 126, 127 are fabricated between metal layers (e.g., M1, M2) on the front side of IC_{T} and metal layers (e.g., BS-M1) on the backside of IC_{T} in order, for example, to enable localized backside biasing and formation of electrical connections to devices within the superstructure 108 of IC_{T}. The TBVs 126 are typically formed by plasma etching.

The present invention arises from the recognition that conventional fabrication of TBVs 126 by plasma etching may cause damage to the FETs of the top integrated circuit, IC_{T}. The present invention provides integrated circuit structures and fabrication methods that substantially prevent or mitigates such damage.

### SUMMARY

The present invention encompasses integrated circuit structures and fabrication methods that substantially prevent or mitigate damage that plasma etching may cause to the FETs of a top integrated circuit in a 3-D IC stack. Embodiments of such IC structures include (1) use of substrate contacts (S-contacts) within the top integrated circuit, IC_{T}, of the 3-D IC stack connected to the gates of FETs that may be damaged by plasma etching, and (2) selective retention of the substrate/handle wafer of IC_{T} aligned and in electrical contact with such S-contacts so as to conduct plasma charge away from the gate oxide of the protected FETs. In addition, the novel integrated circuit structures provide an additional benefit by providing thermal dissipation paths (heat sinks) for the 3-D IC stack.

One embodiment of the invention includes a three-dimensional IC stack, including a first IC including a bonding face, and a second IC including a bonding face, at least one substrate contact electrically coupled to a corresponding gate of a FET within the second IC, and at least one patterned post-etching handle remnant aligned and in electrical contact with a corresponding one of the at least one substrate contact, wherein the bonding face of the second IC is bonded to the bonding face of the first IC.

One process for fabricating embodiments of invention includes fabricating a first IC including a bonding face; fabricating a second IC including a bonding face, a substrate/handle wafer, and at least one substrate contact electrically coupled between a corresponding gate of a FET within the second IC and the substrate/handle wafer; bonding the bonding face of the second IC to the bonding face of the first IC; masking and etching the substrate/handle wafer of the second IC to remove the substrate/handle wafer except for at least one post-etching handle remnant aligned and in electrical contact with a corresponding one of the at least one substrate contact; and fabricating a backside structure for the second IC in regions not covered by the at least one post-etching handle remnant.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a cross-sectional view of one stage of fabrication of a prior art 3-D IC involving a stack of two 2-D ICs.

FIG. 1B is a cross-sectional view of a further stage of fabrication of the prior art 3-D IC of FIG. 1A.

FIG. 1C is a cross-sectional view of yet a further stage of fabrication of the prior art 3-D IC of FIG. 1A.

FIG. 2 is a cross-sectional view of a 3-D IC fabricated in accordance with the present invention.

FIGS. 3A-3C are cross-sectional views of successive stages of fabrication of an example 3-D IC made in accordance with the present invention.

FIG. 4 is a top plan view of IC_{T} within the 3-D IC stack shown in FIG. 3C.

FIG. 5 is a plan view (not to scale) of an IC die having a die seal ring.

FIG. 6 is a process flow chart depicting one method of fabricating a 3-D IC stack in accordance with the present invention.

Like reference numbers and designations in the various drawings indicate like elements unless the context requires otherwise.

### DETAILED DESCRIPTION

The present invention encompasses integrated circuit structures and fabrication methods that substantially prevent or mitigate damage that plasma etching may cause to the FETs of a top integrated circuit in a 3-D IC stack. Embodiments of such IC structures include (1) use of substrate contacts (S-contacts) within the top integrated circuit, IC_{T}, of the 3-D IC stack connected to the gates of FETs that may be damaged by plasma etching, and (2) selective retention of the substrate/handle wafer of IC_{T} aligned and in electrical contact with such S-contacts so as to conduct plasma charge away from the gate oxide of the protected FETs. In addition, the novel integrated circuit structures provide an additional benefit by providing thermal dissipation paths (heat sinks) for the 3-D IC stack.

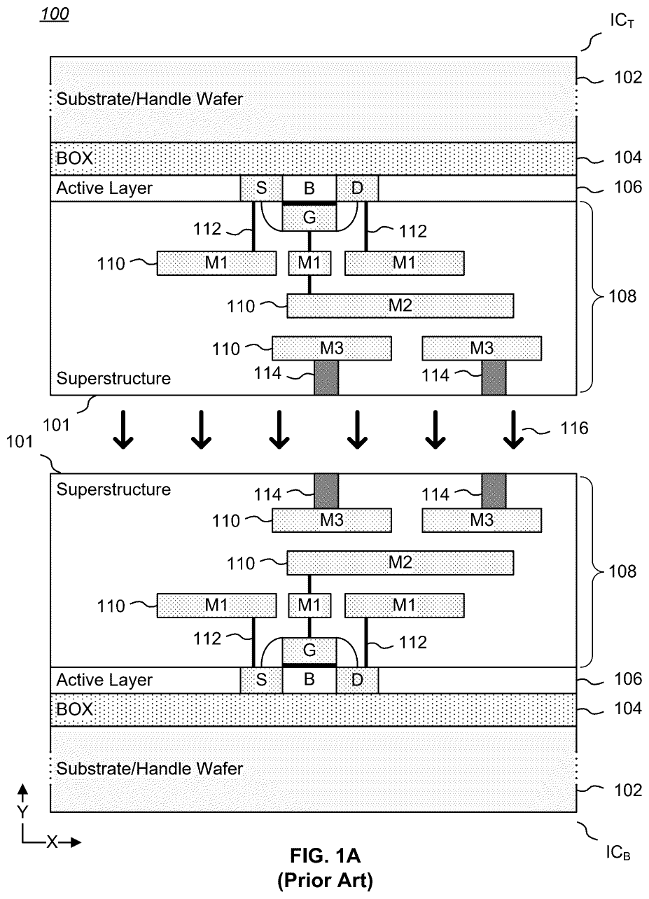

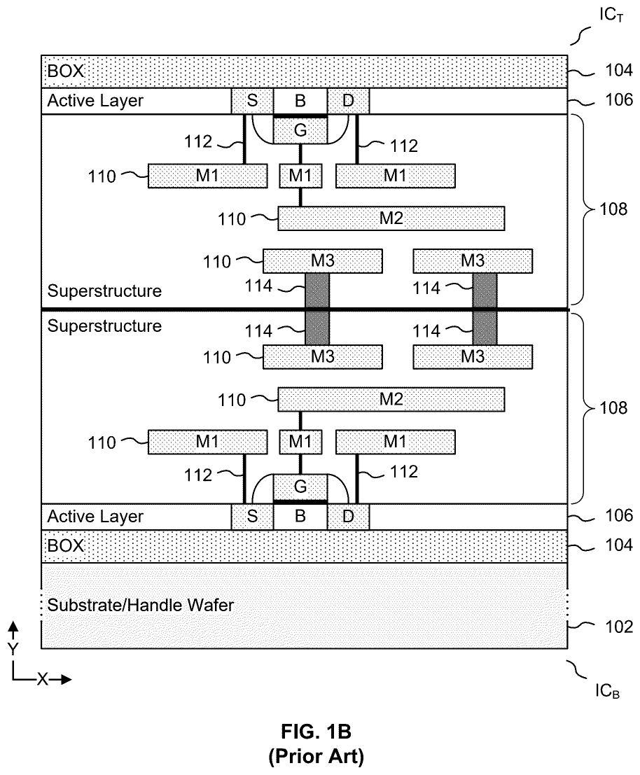

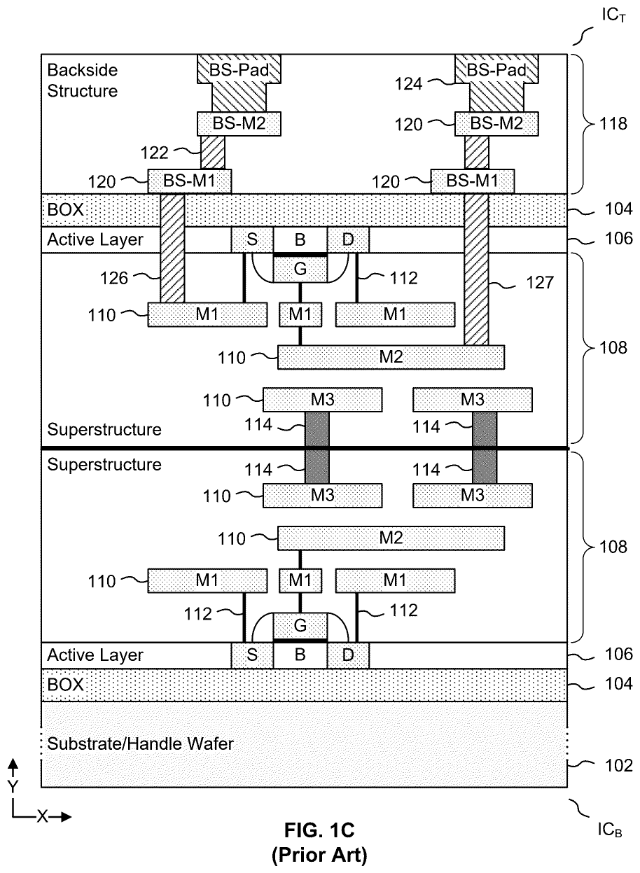

Analyzing the performance of 3-D IC stacks like the example shown in FIG. 1C, the inventors discovered that use of plasma etching across the backside of the top IC, IC_{T}, in a 3-D IC stack induced damage to the FETs within that IC. It was concluded that such damage resulted because there was no electrical path to conduct plasma charge away from the gate oxide of FETs that connected to the backside structure 118 through TBVs. For example, in FIG. 1C, TBV 127 connects through M2 and M1 of IC_{T} to the gate G of the illustrated FET. Plasma etching during fabrication of various layers within the backside structure 118 can cause electrical charge to be conveyed by TBV 127 to and trapped within the gate G of the FET. This results in a detrimental shift in the threshold voltage V_{TH} of the FET. For example, in some particular analyzed 3-D IC stacks, the shift in V_{TH} for the FETs in IC_{T} has been in the range of about 40 mV to about 60 m V. In addition, the plasma-induced damage resulted in leakage degradation, which has a potentially detrimental impact on various circuits and devices within 3-D IC stack product dies, such as level shifters and ESD devices. Accordingly, trapped plasma-induced charges can lead to long term reliability concern for such product dies.

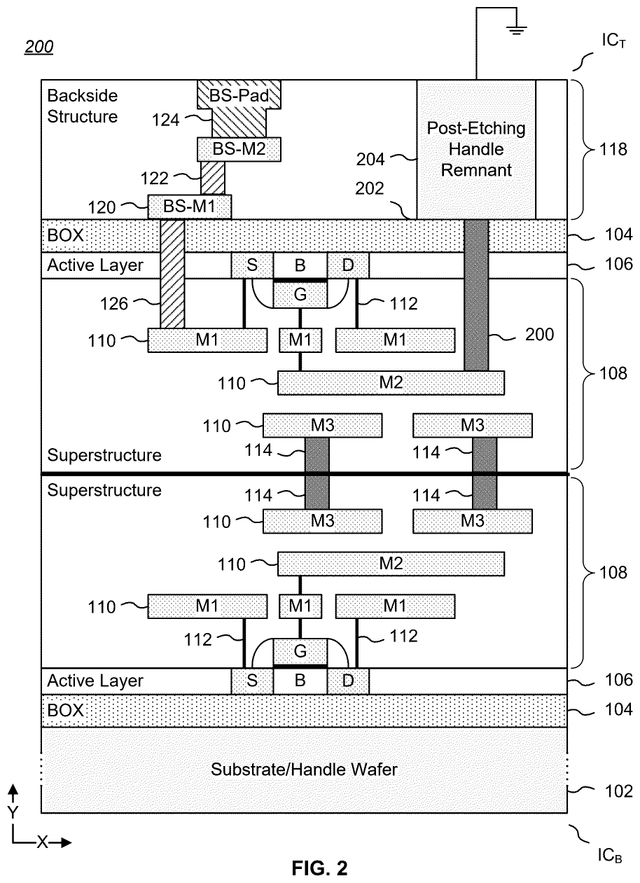

FIG. 2 is a cross-sectional view of a 3-D IC 200 fabricated in accordance with the present invention. This example shows a first IC_{T} bonded to a second IC_{B}. In this particular example, both ICs are fabricated using a silicon-on-insulator (SOI) fabrication process, but may or may not be identical. However, the invention is not limited to use of constituent SOI ICs, and may be used with any 3-D IC fabrication technology in which transistors or other devices may be damaged by backside plasma etching of the top IC.

In FIG. 2, for FETs that may be damaged by use of TBVs (e.g., TBV 127 in FIG. 1C), rather than using a TBV formed by plasma etching, instead an S-contact 200 is formed during the fabrication of the front-side superstructure 108 of IC_{T}. Thus, in FIG. 2, while some TBVs (e.g., TBV 126) may still be formed by plasma etching during fabrication of the backside structure 118, an S-contact (e.g., S-contact 200) is formed during “normal” front-side processing to be in electrical contact with the gate G of the illustrated FET through metal layers M2 and M1.

S-contacts can provide resistive discharge paths to the active layer and/or to the gates G of FETs within IC_{T} by resistively connecting regions or structures of such layers to a high-resistivity semiconductor substrate. An S-contact can be formed of any low-resistivity conductive material or materials, such as polysilicon and various metals (e.g., tungsten, copper, etc.), and can be made of the same material or comprise several materials, enabling a piece-wise construction of the S-contact. Details on the structure and fabrication of S-contacts may be found, for example, in U.S. patent application Ser. No. 15/824,990, filed Nov. 28, 2017, entitled “S-Contact for SOI”, which is hereby incorporated by reference.

In the illustrated example of IC_{T} shown in FIG. 2, the S-contact 200 is formed during front-side processing so as to electrically connect a portion of the M2 metal layer (which is connected to the gate G of the illustrated FET through a portion of the M1 metal layer) through the active layer 106 and BOX layer 104 to the original substrate/handle wafer 102 of IC_{T} at the juncture 202 of the BOX layer 104 and the substrate/handle wafer 102. Importantly, during subsequent backside processing of IC_{T}, the substrate/handle wafer 102 is not fully removed, as in conventional processing. Instead, the substrate/handle wafer 102 is masked and selectively etched (i.e., patterned), typically with an anisotropic etchant such as tetra methyl ammonium hydroxide (TMAH). The masking is designed to map overlaying portions of the substrate/handle wafer 102 to corresponding S-contacts 200. Selective etching leaves one or more post-etching handle remnants 204 of the original substrate/handle wafer 102 aligned and in electrical contact with corresponding S-contacts 200. During subsequent backside processing of IC_{T}, the post-etching handle remnants 204 may be electrically grounded so that plasma charge is conveyed to ground rather than being trapped on the gates G of FETs within IC_{T}.

As should be apparent from FIG. 2, the presence of paired conductive S-contacts 200 and post-etching handle remnants 204 also provides thermal dissipation paths (heat sinks) for the 3-D IC stack 200. Thus, the impact of self-heating caused by the illustrated FET is reduced by conveyance of some of that thermal energy out through the paired conductive S-contacts 200 and post-etching handle remnants 204 to a suitable heat sink (e.g., within a package for the 3-D IC stack 200). The inventors have observed that self-heating of a conventional 3-D IC stack can result in up to about 10% degradation of a FET's saturation drain current, IDSAT. Mitigating the effects of such self-heating using the present invention thus improves the performance of a 3-D IC stack.

By eliminating or mitigating trapped plasma-induced charges and reducing the effects of self-heating, embodiments of the present invention help mitigate major quality risk by reducing the probability of shipping defective or potentially defective parts.

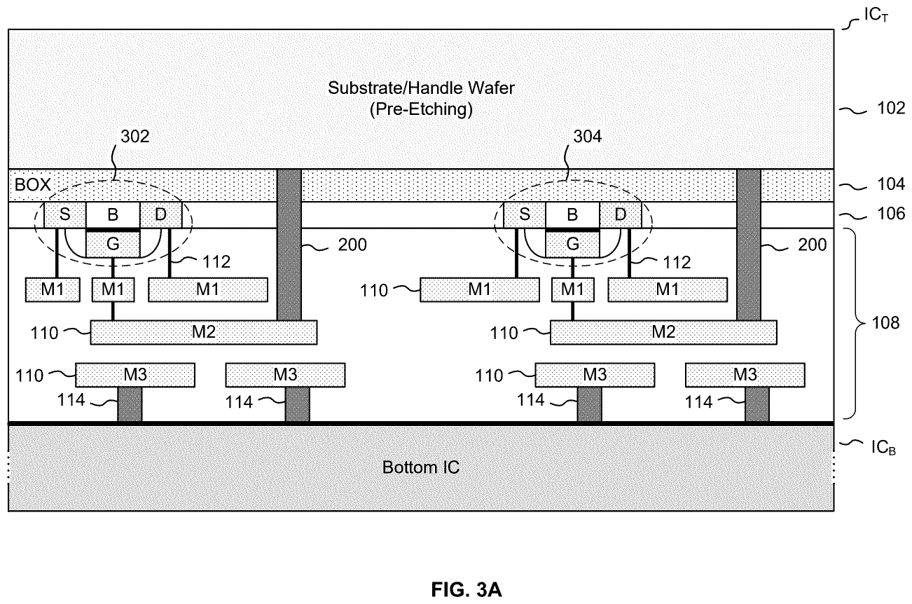

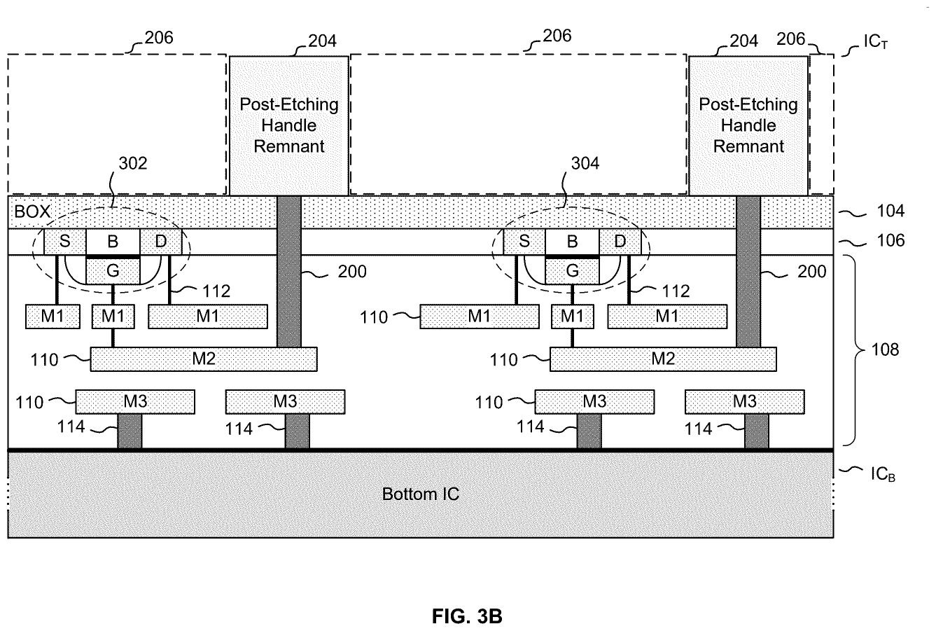

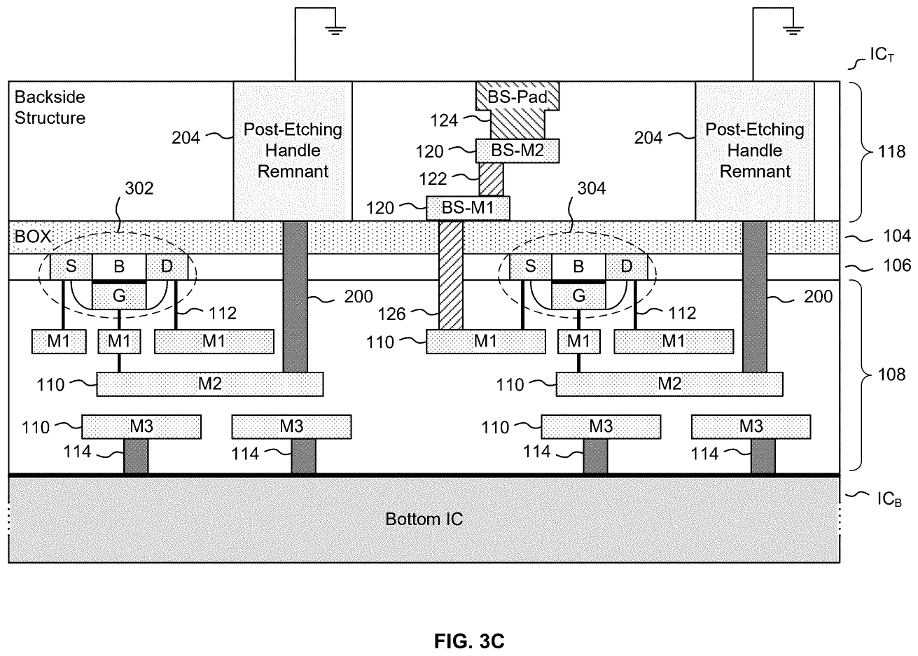

FIGS. 3A-3C are cross-sectional views of successive stages of fabrication of an example 3-D IC made in accordance with the present invention. The dimensions for the various elements are not to scale; some dimensions may be greatly exaggerated vertically and/or horizontally for clarity or emphasis.

FIG. 3A shows a first integrated circuit, IC_{T}, bonded to a simplified representation of a second integrated circuit, IC_{B}. The substrate/handle wafer 102 is still attached to IC_{T}, which in this example includes two FETs (enclosed by dashed ovals 302, 304); as should be clear, while the illustrations shown only one or two FETs, a typical IC may include thousands to billions of FETs. In the illustrated example, S-contacts 200 have been formed in the superstructure 108 of IC_{T} that connect portions of the M2 metal layer 110 to the substrate/handle wafer 102. Notably, if plasma etching is used to fabricate the superstructure 108 of IC_{T} (including the S-contacts 200) before bonding IC_{T} to IC_{B}, plasma induced charge may be conveyed to ground through the substrate/handle wafer 102 (e.g., to a chuck holding the IC_{T} wafer).

In FIG. 3B, the substrate/handle wafer 102 has been masked and etched to form post-etching handle remnants 204 of the substrate/handle wafer 102, along with voids 206 (shown in dashed outline) between the post-etching handle remnants 204. Complete removal of the substrate/handle wafer 102, as in conventional IC fabrication, would leave no conductive path to ground for plasma-induced charge that may be conveyed to the gates of the FETs 302, 304. However, by forming post-etching handle remnants 204 aligned and in electrical contact with corresponding S-contacts 200 that electrically couple to the gates G of FETs within IC_{T}, it is possible to ground (and thus protect) the gates G during subsequent plasma etching steps.

FIG. 3C shows that additional fabrication steps have between performed within the former voids 206 shown in FIG. 3B to form the remainder of a backside structure 118. The backside structure 118 generally comprises multiple layers that may include one or more backside metal levels 120 (e.g., BS-M1, BS-M2), internal vias 122, and backside bonding vias 124 (e.g., BS-Pad) within a matrix of ILD material. Fabrication of the backside structure 118 may even include formation of TBVs 126, such as by plasma etching, so long as the particular TBVs 126 cannot convey charge to a FET gate. The backside structure 118 otherwise differs from a conventional 3-D IC stack design by also including post-etching handle remnants 204 coupled to corresponding S-contacts 200.

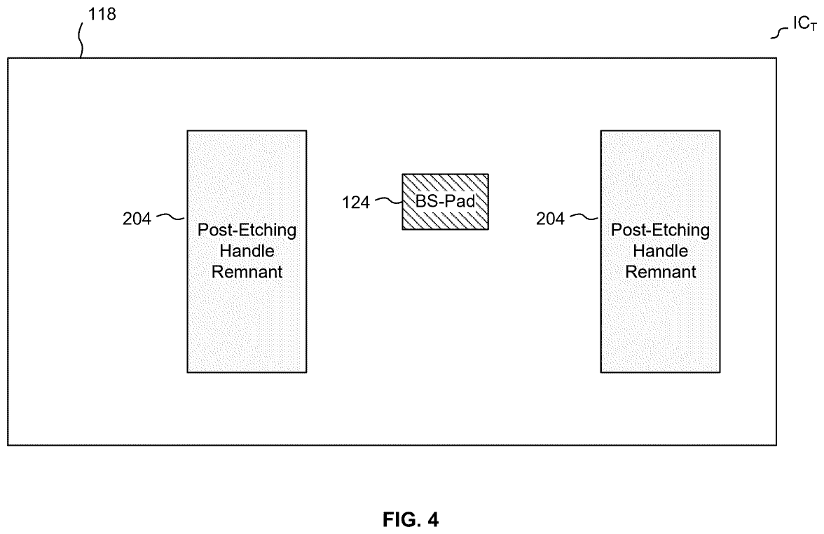

FIG. 4 is a top plan view of IC_{T} within the 3-D IC stack shown in FIG. 3C. Apparent on the surface of IC_{T} are the post-etching handle remnants 204 and a backside bonding via 124. Although shown as rectangles in FIG. 4, the post-etching handle remnants 204 may have any desired shape (e.g., rectangular, square, circular, octagonal, etc.) suitable for electrically connecting to underlying S-contacts 200 and compatible with a chosen fabrication process.

In the manufacture of ICs, in many cases, it is advantageous to use die seals around the edges of individual IC dies (also known as “chips”). A die seal can provide protection from damage to a substrate of an IC die (and associated circuitry), and in particular protects the substrate and internal circuits of an IC die from structural stresses that occur when dicing a semiconductor wafer into individual IC dies. Die seals are typically formed by depositing metal lines in all metal layers around the perimeter of a die to stop propagation of die cracks and contaminants. With respect to 3-D IC stacks as described in this disclosure, the metal layers comprising a die seal may be continued within a backside structure 118 of IC_{T}.

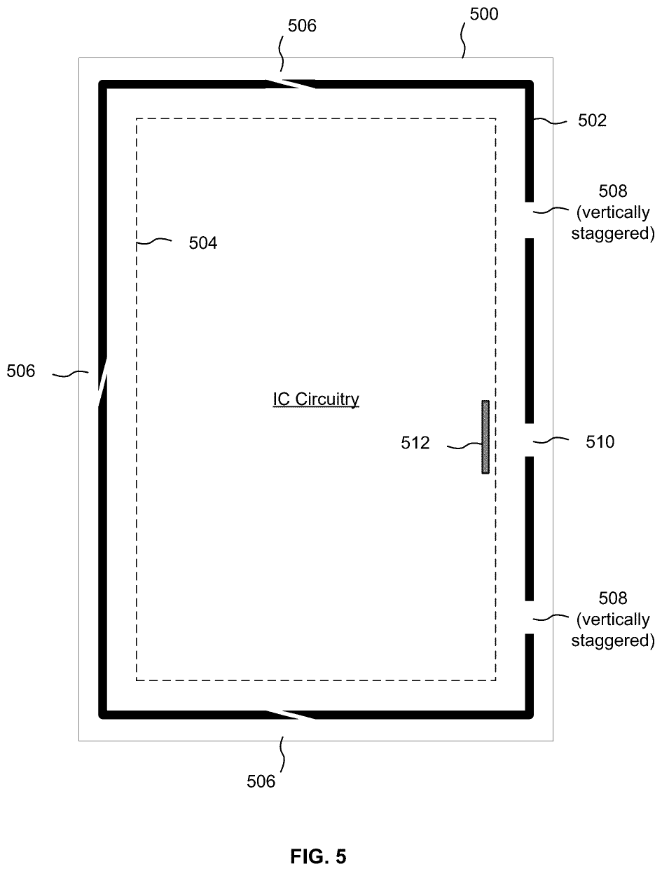

A die seal may be an unbroken ring around a die, or may be interrupted by a gap at one or more sections for electrical isolation in order to mitigate or eliminate induced currents through the die seal, which is particularly useful for radio frequency applications. For example, FIG. 5 is a plan view (not to scale) of an IC die 500 having a die seal ring 502. Typically, most or all microelectronic circuitry is located inside the die seal ring 502, as suggested by the dashed box 504.

In some embodiments, an angled gap 506 is provided in the die seal. In such embodiments, the multiple metal layers forming such angled gaps 506 may be vertically aligned. In other embodiments, one or more straight (rather than angled) but vertically staggered gaps 508 may be provided. In vertically staggered straight gaps 508, the multiple metal layers forming such gaps are offset with respect to other conductive layers such that each gap in each conductor layer has at least one conductor on top and/or below it to ensure that the die seal will perform its desired protective function.

If straight gaps 510 (not vertically staggered) are used, to ensure that cracks that might form during a cutting operation do not propagate through a straight gap, at least a portion of a parallel conductor strip (not shown) may be provided adjacent to (but spaced from) and overlapping each straight gap 510 so that there is always a die seal segment blocking any direct path from a die edge.

S-contacts exhibit essentially the same physical properties as a die seal segment while being electrically isolated from the die seal. Thus, in some cases, S-contacts 512 may be provided spaced from a straight gate 510 but configured to electrically and mechanically connect the different metal layers comprising a die seal 502. S-contacts 512 may also be formed adjacent to and overlapping angled gaps 506 and/or vertically staggered straight gaps 508. Accordingly, a die seal 502 is preserved with respect to any direct path from a die edge without requiring a large IC die or unnecessarily consuming extra IC area within the perimeter of the die seal.

Further discussion of die seals, particularly interrupted or “broken” die seals, may be found in U.S. Pat. No. 10,971,419 B2, filed Jan. 18, 2019, issued Apr. 6, 2021, entitled “Method and Apparatus for Reducing Noise on Integrated Circuit using Broken Die Seal”, which is hereby incorporated by reference.

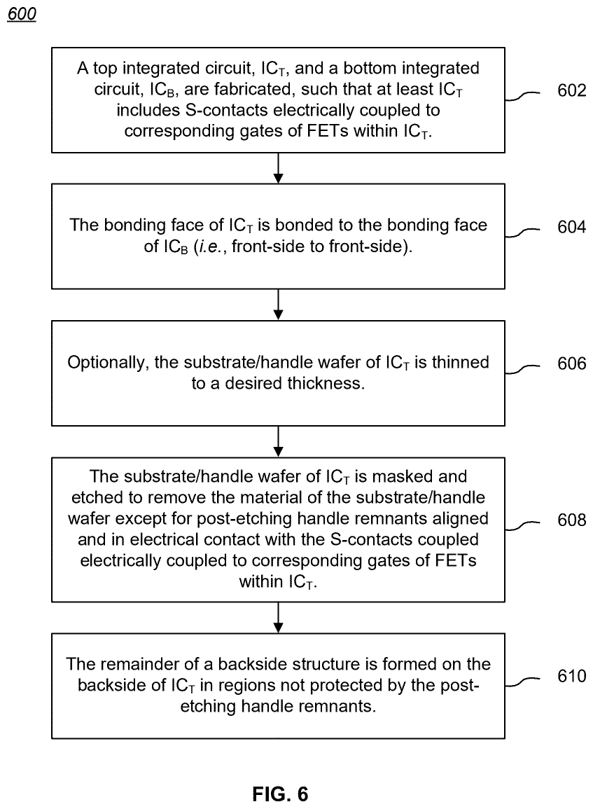

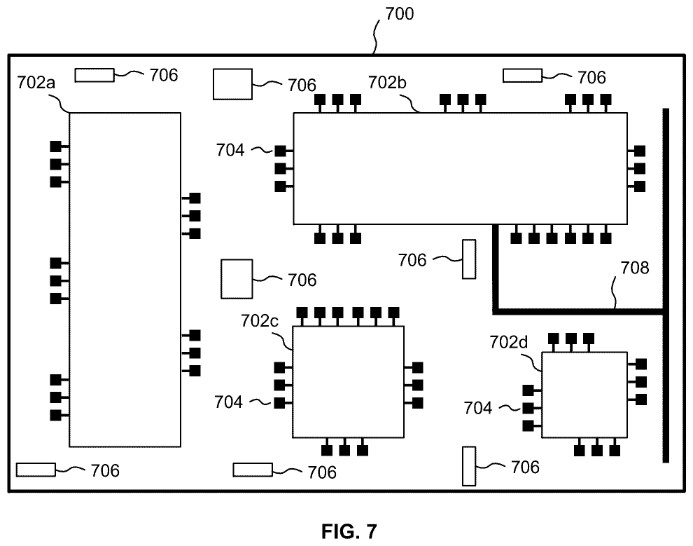

FIG. 6 is a process flow chart 600 depicting one method of fabricating a 3-D IC stack in accordance with the present invention. It should be understood that other process steps may be included as desired, such as wafer polishing, wafer cleaning, etc., and that the order of some steps may be different for some applications and/or to accommodate different fabrication facility processes.
BLOCK 602: A top integrated circuit, IC_{T}, and a bottom integrated circuit, IC_{B}, are fabricated, such that at least IC_{T} includes S-contacts electrically coupled to corresponding gates of FETs within IC_{T}.
BLOCK 604: The bonding face of IC_{T} is bonded to the bonding face of IC_{B} (i.e., front-side to front-side).
BLOCK 606: Optionally, the substrate/handle wafer 102 of IC_{T} is thinned to a desired thickness.
BLOCK 608: The substrate/handle wafer 102 of IC_{T} is masked and etched to remove the material of the substrate/handle wafer 102 except for post-etching handle remnants 204 aligned and in electrical contact with the S-contacts coupled electrically coupled to corresponding gates of FETs within IC_{T}.
BLOCK 610: The remainder of a backside structure 118 is formed on the backside of IC_{T} in regions not covered by the post-etching handle remnants 204.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

As one example of further integration of embodiments of the present invention with other components, FIG. 7 is a top plan view of a substrate 700 that may be, for example, a printed circuit board or chip module substrate (e.g., a thin-film tile). In the illustrated example, the substrate 700 includes multiple ICs 702a-702d having terminal pads 704 which would be interconnected by conductive vias and/or traces on and/or within the substrate 700 or on the opposite (back) surface of the substrate 700 (to avoid clutter, the surface conductive traces are not shown and not all terminal pads are labelled). The ICs 702a-702d may embody, for example, signal switches, active and/or passive filters, amplifiers (including one or more LNAs), and other circuitry. For example, IC 702b may be a 3-D IC stack like the example shown in FIG. 2.

The substrate 700 may also include one or more passive devices 706 embedded in, formed on, and/or affixed to the substrate 700. While shown as generic rectangles, the passive devices 706 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 700 to other passive devices 706 and/or the individual ICs 702a-702d.

The front or back surface of the substrate 700 may be used as a location for the formation of other structures. For example, one or more antennae may be formed on or affixed to the front or back surface of the substrate 700; one example of a front-surface antenna 708 is shown, coupled to an IC die 702b, which may include RF front-end circuitry. Thus, by including one or more antennae on the substrate 700, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

The term “MOSFET”, as used in this disclosure, includes any field effect transistor (FET) having an insulated gate whose voltage or charge level determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, GaAs HBT, GaN HEMT, GaAs pHEMT, MESFET, InP HBT, InP HEMT, FinFET, GAAFET, and SiC-based device technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A three-dimensional integrated circuit (IC) stack, including:
(a) a first IC including a bonding face; and
(b) a second IC including:
(1) a bonding face;
(2) at least one substrate contact electrically coupled to a corresponding gate of a field-effect transistor (FET) within the second IC; and
(3) at least one patterned post-etching handle remnant aligned and in electrical contact with a corresponding one of the at least one substrate contact;
wherein the bonding face of the second IC is bonded to the bonding face of the first IC.

2. The three-dimensional IC stack of claim 1, wherein the first IC and/or the second IC are fabricated using a silicon-on-insulator fabrication process.

3. The three-dimensional IC stack of claim 1, wherein the second IC further includes a superstructure including one or more metal layers, an active layer in and on which the FET is formed, and a BOX layer.

4. The three-dimensional IC stack of claim 3, wherein the at least one substrate contact is electrically coupled between the corresponding gate of the FET and the corresponding at least one patterned post-etching handle remnant through at least one of the one or more metal layers.

5. The three-dimensional IC stack of claim 3, wherein the at least one substrate contact penetrates through the active layer and the BOX layer and is electrically coupled between at least one of the one or more metal layers and the corresponding at least one patterned post-etching handle remnant.

6. The three-dimensional IC stack of claim 1, wherein the second IC includes a die seal ring.

7. A three-dimensional integrated circuit (IC) stack, including:
(a) a first IC including a bonding face; and
(b) a second IC including:
(1) a superstructure including one or more metal layers, an active layer in and on which a field-effect transistor (FET) is formed, a BOX layer; and a bonding face;
(2) a substrate contact electrically coupled to a gate of the FET; and
(3) at least one post-etching handle remnant aligned and in electrical contact with the substrate contact;
wherein the bonding face of the second IC is bonded to the bonding face of the first IC.

8. The three-dimensional IC stack of claim 7, wherein the substrate contact is electrically coupled between the gate of the FET and the post-etching handle remnant through at least one of the one or more metal layers.

9. The three-dimensional IC stack of claim 7, wherein the substrate contact penetrates through the active layer and the BOX layer and is electrically coupled between at least one of the one or more metal layers and the post-etching handle remnant.

10. The three-dimensional IC stack of claim 7, wherein the second IC includes a die seal ring.

11. A method of fabricating a three-dimensional integrated circuit (IC) stack, including:
(a) fabricating a first IC including a bonding face; and
(b) fabricating a second IC including:
(1) a bonding face;
(2) at least one substrate contact electrically coupled to a corresponding gate of a field-effect transistor (FET) within the second IC; and
(3) at least one patterned post-etching handle remnant aligned and in electrical contact with a corresponding one of the at least one substrate contact;
(c) bonding the bonding face of the second IC to the bonding face of the first IC.

12. The method of claim 11, further including fabricating the first IC and/or the second IC using a silicon-on-insulator fabrication process.

13. The method of claim 11, wherein the second IC further includes a superstructure including one or more metal layers, an active layer in and on which the FET is formed, and a BOX layer.

14. The three-dimensional IC stack of claim 13, wherein the at least one substrate contact is electrically coupled between the corresponding gate of the FET and the corresponding at least one patterned post-etching handle remnant through at least one of the one or more metal layers.

15. The method of claim 13, wherein the at least one substrate contact penetrates through the active layer and the BOX layer and is electrically coupled between at least one of the one or more metal layers and the corresponding at least one patterned post-etching handle remnant.

16. The method of claim 11, wherein the second IC includes a die seal ring.

17. A method of fabricating a three-dimensional integrated circuit (IC) stack, including:
(a) fabricating a first IC including a bonding face;
(b) fabricating a second IC including:
(1) a bonding face;
(2) a substrate/handle wafer; and
(3) at least one substrate contact electrically coupled between a corresponding gate of a field-effect transistor (FET) within the second IC and the substrate/handle wafer;
(c) bonding the bonding face of the second IC to the bonding face of the first IC;
(d) masking and etching the substrate/handle wafer of the second IC to remove the substrate/handle wafer except for at least one post-etching handle remnant aligned and in electrical contact with a corresponding one of the at least one substrate contact; and
(e) fabricating a backside structure for the second IC in regions not covered by the at least one post-etching handle remnant.

18. The method of claim 17, further including thinning the substrate/handle wafer of the second IC before masking and etching the substrate/handle wafer of the second IC.

19. The method of claim 17, further including thinning the substrate/handle wafer of the second IC after bonding the bonding face of the second IC to the bonding face of the first IC, and before masking and etching the substrate/handle wafer of the second IC.

20. The method of claim 17, further including fabricating a die seal ring as part of the second IC.
